(19) United States
(12) Patent Application Publication
(10) Pub. No.: US 2015/0198292 A1
(43) Pub. Date: Jul. 16, 2015

(54) LIGHT EMITTING DIODE (LED) DEVICES, SYSTEMS, AND METHODS FOR PROVIDING CUSTOMIZED BEAM SHAPING

(71) Applicant: Cree, Inc., Durham, NC (US)

(72) Inventor: Carlton S. Jones, Boxford, MA (US)

(21) Appl. No.: 14/156,161

(22) Filed: Jan. 15, 2014

(51) Int. Cl. F21K 99/00; F21S 8/08; H01L 25/075; F21S 8/10; H01L 33/54; H01L 33/48

(52) U.S. Cl. CPC F21K 9/30; H01L 33/54; H01L 33/486; H01L 25/0753; F21S 48/115; F21S 8/088; F21K 9/90; F21Y 2101/02

(57) ABSTRACT

Light emitting diode (LED) devices, systems, and methods for targeted beam shaping are provided. In some aspects, LED devices and methods include providing a submount and a light emission area disposed over the submount. The light emission area includes a plurality of LED chips mounted over the submount. At least some of the LED chips are provided in a first non-circular shape, such that upon illumination of the LED chips, a resultant beam pattern of light on the surface is substantially the same as the first shape. LED systems and methods include providing LEDs arranged according to a specific shape, intensity pattern, or a color pattern. Upon illumination of the LED chips, a shape, intensity pattern, or color pattern of light emitted by the system substantially corresponds to the shape, intensity pattern, or color pattern of the light emission area.

### TECHNICAL FIELD

The subject matter disclosed herein relates generally to light emitting diode (LED) devices, systems, and methods. More particularly, the subject matter disclosed herein relates to systems and methods of producing customized beam shaping and light emission via easily customized LED devices.

### BACKGROUND

Light emitting diode (LED) devices containing LED chips are currently used in many different general lighting applications and systems, for example, in products targeting replacement of incandescent, fluorescent, and metal halide high-intensity discharge (HID) products within various lighting applications (e.g., commercial lighting, street lighting, automotive lighting, home lighting, etc.).

As the number of LED lighting applications increases, lighting device manufacturers and/or designers increasingly face pressure to make products capable of producing various different and specific light beam patterns at various different and specific colors and/or light intensities. To achieve various beam patterns and light intensity patterns, conventional devices, systems, and methods employ specifically shaped (e.g., customized) secondary optics for manipulating beam and/or light intensity patterns. The cost of providing LED devices, systems, and methods increases when customized secondary optics are required. In addition, the ease of manufacture, the cost of servicing, and/or the replacement of LED chips or other components of devices and systems utilizing customized secondary optics are each also negatively impacted.

Accordingly, a need remains for increasing the utilization of LED devices within applications requiring specific or customized beam patterns at a reduced cost while promoting ease of manufacture.

### SUMMARY

In accordance with this disclosure, novel light emitting diode devices, systems, and methods are provided and can be customized for use in a variety of lighting applications, including industrial and commercial lighting products. In some aspects, a light emitting device comprises a submount and a light emission area configured to cast light towards a surface provided a distance away from the submount. The light emission area includes a plurality of light emitting diode (LED) chips mounted over the submount. At least some of the LED chips are provided in a first (e.g., non-circular) shape, such that upon illumination of the LED chips, a resultant beam pattern of light on the surface is substantially the same as the first shape.

In some aspects, a light emitting system is disclosed. The system comprises a light emitting device comprising a submount and a light emission area. The light emission area includes a plurality of LED chips mounted over the submount. The light emission area comprises a specific shape, intensity pattern, or a color pattern. The system further comprises a housing disposed about a portion of the light emitting device. Upon illumination of the LED chips, a shape, intensity pattern, or color pattern of light emitted thereby substantially corresponds to the shape, intensity pattern, or color pattern of the light emission area.

A method of providing customized beam shaping is also disclosed. The method comprises providing a plurality of LED chips over a submount and arranging the plurality of LED chips within a shape, according to LED chip intensity, or according to LED chip color. The method further comprises illuminating the LED chips, such that upon illumination, a resultant beam pattern of light corresponds to the shape, intensity, or color of the LED chips.

It is, therefore, an object of the present disclosure herein to provide easy to manufacture light emitting diode devices, systems, and methods adapted to provide customized beam shaping. These and other objects of the present disclosure as can become apparent from the disclosure herein are achieved, at least in whole or in part, by the subject matter disclosed herein.

### BRIEF DESCRIPTION OF THE DRAWINGS

A full and enabling disclosure of the present subject matter including the best mode thereof to one of ordinary skill in the art is set forth more particularly in the remainder of the specification, including reference to the accompanying figures, in which:

FIG. 1A is a top plan view illustrating a light emitting diode (LED) device according to the disclosure herein;

FIG. 1B is a sectional view illustrating the LED device according to FIG. 1A of the disclosure herein;

FIG. 2 is a top plan view illustrating a portion of an LED device according to the disclosure herein;

FIG. 3 is a schematic illustration illustrating an LED system according to the disclosure herein;

FIG. 4 is a second schematic illustration illustrating an LED system according to the disclosure herein;

FIG. 5 is a top plan view illustrating an LED device according to the disclosure herein;

FIG. 6 is a lighting fixture incorporating LED devices and systems according to the disclosure herein;

FIGS. 7A and 7B are LED devices for systems and methods for providing desired beam shaping according to the disclosure herein;

FIGS. 8A and 8B are LED devices for systems and methods providing desired beam shaping according to the disclosure herein; and

FIGS. 9A and 9B are LED devices for systems and methods providing desired beam shaping according to the disclosure herein.

### DETAILED DESCRIPTION

The subject matter disclosed herein is directed to systems and methods of providing customized beam shaping and light emission patterns via easily customized LED devices. That is, the subject matter disclosed herein is directed to shaping the source of the light (e.g., the lighting devices and systems) to a desired pattern of light, thereby obviating the need for customized secondary optics for shaping beam and intensity patterns. Typically, the shape of a light source (e.g., metal filament, round array, or squared array) is used as is, and the secondary optics are tasked with providing a non-round or non-squared beam pattern. The process of re-shaping via secondary optics decreases overall optical and luminaire efficiency, while increasing system costs.

In some aspects, LED devices and systems provided herein comprise customized light emission areas that are easily configurable for providing targeted, specific, customized, and/or standardized beam patterns. While LED devices, systems, and methods provided herein may include and/or be housed within a simple secondary lens, such devices and systems advantageously obviate the need for costly and complex secondary lenses or optics that are specifically designed to affect aspects of beam patterns (e.g., shape, intensity, color, etc.).

The subject matter herein discloses light devices and systems comprising light sources corresponding in shape to the desired beam-pattern. This increases efficiency of the LED devices and systems (e.g., by increasing a fitted target efficacy). Devices and systems herein require less heat, less power, and as the devices and systems provide more targeted beam patterns, devices and systems herein waste less light than conventional devices.

In some aspects, a light emitting device comprises a submount and a light emission area configured to cast light towards a surface provided a distance away from the submount. The light emission area includes a plurality of light emitting diode (LED) chips mounted over the submount. At least some chips of the plurality of LED chips are provided in a first non-circular shape, such that upon illumination of the LED chips, a resultant beam pattern of light on the surface is substantially the same as the first shape

In some aspects, a light emitting system is disclosed. The system comprises a light emitting device comprising a submount and a light emission area. The light emission area includes a plurality of LED chips mounted over the submount. The light emission area comprises a specific shape, intensity pattern, or a color pattern. The system further comprises a housing disposed about a portion of the light emitting device. Upon illumination of the LED chips, a shape, intensity pattern, or color pattern of light emitted thereby substantially corresponds to the shape, intensity pattern, or color pattern of the light emission area.

A method of providing customized beam shaping is also disclosed. The method comprises providing a plurality of LED chips over a submount and arranging the plurality of LED chips within a shape, according to LED chip intensity, or according to LED chip color. The method further comprises illuminating the LED chips, such that upon illumination, a resultant beam pattern of light corresponds to the shape, intensity, or color of the LED chips.

Each example and/or embodiment described herein is provided to explain the subject matter and not as a limitation. In fact, features illustrated or described as part of one embodiment can be used in another embodiment to yield still a further embodiment. It is intended that the subject matter disclosed and envisioned herein covers such modifications and variations.

As illustrated in the various figures, some sizes of structures or portions may be exaggerated relative to other structures or portions for illustrative purposes and, thus, are provided to illustrate the general structures of the present subject matter and may or may not be drawn to scale. Furthermore, various aspects of the present subject matter are described with reference to a structure or a portion being formed on other structures, portions, or both. As will be appreciated by those of skill in the art, references to a structure being formed “on” or “above” another structure or portion contemplates that additional structure, portion, or both may intervene. References to a structure or a portion being formed “on” another structure or portion without an intervening structure or portion are described herein as being formed “directly on” the structure or portion. Similarly, it will be understood that when an element is referred to as being “connected”, “attached”, or “coupled” to another element, it can be directly connected, attached, or coupled to the other element, or intervening elements may be present. In contrast, when an element is referred to as being “directly connected”, “directly attached”, or “directly coupled” to another element, no intervening elements are present.

Furthermore, relative terms such as “on”, “above”, “upper”, “top”, “lower”, or “bottom” are used herein to describe one structure's or portion's relationship to another structure or portion as illustrated in the figures. It will be understood that relative terms such as “on”, “above”, “upper”, “top”, “lower” or “bottom” are intended to encompass different orientations of the device, system, or component in addition to the orientation depicted in the figures. For example, if the device, system, or component in the figures is turned over, structure or portion described as “above” other structures or portions would now be oriented “below” the other structures or portions. Likewise, if the device, system, or component in the figures are rotated along an axis, structure or portion described as “above”, other structures or portions would be oriented “next to” or “left of” the other structures or portions. Like numbers refer to like elements throughout.

Unless the absence of one or more elements is specifically recited, the terms “comprising”, including”, and “having” as used herein should be interpreted as open-ended terms that do not preclude the presence of one or more elements.

As used herein with respect to lenses, the term “asymmetric”, when unmodified by any further limiting description, refers to a shape which is not rotationally symmetric about any axis perpendicular to a base plane.

As used herein with respect to lenses, the term “beam pattern”, when unmodified by any further limiting description, refers to any aspects of a desired light output such as a shape, intensity, spread (e.g. lateral and vertical), or color of light output, or a far-field pattern of the light output, and/or variations thereof.

As used herein, the term “irregular”, when unmodified by any further limiting description, refers to any shape that does not have all sides of an equal length and all angles equal. Irregular shapes generally do not have more than two lines of symmetry. However, irregular shapes having more than two lines of symmetry are contemplated. A line of symmetry comprises an imaginary line along which an image can be folded such that both halves match exactly. For example, a rectangle can be categorized as an irregular shape as it does not have all sides equal, and the rectangle has at most two lines of symmetry. In some aspects, irregular shapes can have no more than one line of symmetry. In some aspects, irregular shapes can have no or zero lines of symmetry as the shape is so irregular that it is asymmetric. Even where a shape or configuration may have all sides the same length, such as with an equilateral polygon, the shape or configuration can still be irregular as the angles between segments can be different, making it irregular.

In other aspects, the term “irregular” encompasses any irregular shape, asymmetrical shape, or configuration regardless of lines of symmetry and regardless as to whether all sides and all angles equal. For example and without limitation, an irregular shape or configuration can be any shape or configuration lacking uniformity or symmetry, uneven in shape, position, or arrangement, and/or having at least some or all portions that do not occur or are not disposed at expected or equal intervals or positions. An irregular shape or configuration can in another aspect be a shape or configuration with one or more curved portions or without any curved portions. An irregular shape or configuration can be a shape or configuration with or without one or more protrusion areas that can bring irregularity to the shape or configuration. Irregular in accordance with this disclosure can also be a shape or configuration that includes an aspect ratio between portions that is skewed slightly or drastically such that the shape or configuration is no longer deemed regular. An irregular shape or configuration can also have some portions that may be regular or no portion that is regular.

As used herein, the term “regular”, when unmodified by any further limiting descriptions, refers to any shape having all sides and all angles equal. For example and without limitation, regular shapes comprise a square, circle, oval, equilateral triangle, or any other shape having all sides and all angles equal. Regular shapes can comprise many lines of symmetry as opposed to irregular shapes which generally do not have more than two lines of symmetry.

Light emitting devices according to embodiments described herein can comprise group III-V nitride (e.g., gallium nitride (GaN)) based LED chips or lasers. Fabrication of LED chips and lasers is generally known and only briefly described herein. LED chips or lasers can be fabricated on a growth substrate, for example, a silicon carbide (SiC) substrate, such as those chips or devices manufactured and sold by Cree, Inc. of Durham, North Carolina. Other growth substrates are also contemplated herein, for example and not limited to sapphire, silicon (Si), and GaN. In some aspects, SiC substrates/layers can be 4H polytype silicon carbide substrates/layers. Other SiC candidate polytypes, such as 3C, 6H, and 15R polytypes, however, can be used. Appropriate SiC substrates are available from Cree, Inc., of Durham, N.C., the assignee of the present subject matter, and the methods for producing such substrates are set forth in the scientific literature as well as in a number of commonly assigned U.S. patents, including but not limited to U.S. Pat. No. Re. 34,861, U.S. Pat. No. 4,946,547, and U.S. Pat. No. 5,200,022, the disclosures of which are incorporated by reference herein in their entireties. Any other suitable growth substrates are contemplated herein.

As used herein, the term “Group III nitride” refers to those semiconducting compounds formed between nitrogen and one or more elements in Group III of the periodic table, usually aluminum (Al), gallium (Ga), and indium (In). The term also refers to binary, ternary, and quaternary compounds such as GaN, AlGaN and AlInGaN. The Group III elements can combine with nitrogen to form binary (e.g., GaN), ternary (e.g., AlGaN), and quaternary (e.g., AlInGaN) compounds. These compounds may have empirical formulas in which one mole of nitrogen is combined with a total of one mole of the Group III elements. Accordingly, formulas such as AlₓGa₍₁₋ₓ₎N where 1>x>0 are often used to describe these compounds. Techniques for epitaxial growth of Group III nitrides have become reasonably well developed and reported in the appropriate scientific literature.

Although various embodiments of LED chips disclosed herein can comprise a growth substrate, it will be understood by those skilled in the art that the crystalline epitaxial growth substrate on which the epitaxial layers comprising an LED chip are grown can be removed, and the freestanding epitaxial layers can be mounted on a substitute carrier substrate or substrate which can have different thermal, electrical, structural and/or optical characteristics than the original substrate. The subject matter described herein is not limited to structures having crystalline epitaxial growth substrates and can be used in connection with structures in which the epitaxial layers have been removed from their original growth substrates and bonded to substitute carrier substrates.

Group III nitride based LED chips according to some embodiments of the present subject matter, for example, can be fabricated on growth substrates (e.g., Si, SiC, or sapphire substrates) to provide horizontal chips or devices (with at least two electrical contacts on a same side of the LED chip) or vertical chips or devices (with electrical contacts on opposing sides of the LED chip). Moreover, the growth substrate can be maintained on the LED chip after fabrication or removed (e.g., by etching, grinding, polishing, etc.). The growth substrate can be removed, for example, to reduce a thickness of the resulting LED chip and/or to reduce a forward voltage through a vertical LED chip. A horizontal chip (with or without the growth substrate), for example, can be flip chip bonded (e.g., using solder) to a carrier substrate or printed circuit board (PCB), or wire bonded.

In some aspects, horizontal chips are provided such that they are of a bond-pad-down design which eliminates the need for wire bonds. A vertical chip (with or without the growth substrate) can have a first terminal (e.g., anode or cathode) solder bonded to a carrier substrate, mounting pad, or PCB and a second terminal (e.g., the opposing anode or cathode) wire bonded to the carrier substrate, electrical element, or PCB. Examples of vertical and horizontal LED chip structures are discussed by way of example in U.S. Publication No. 2008/0258130 to Bergmann et al. and in U.S. Pat. No. 7,791,061 to Edmond et al. which issued on Sep. 7, 2010, the disclosures of which are hereby incorporated by reference herein in their entireties.

One or more LED chips and/or portions of LED devices described herein such as portions of the submount, lens, electrical or electrically conductive traces, and/or wire bonds can be at least partially coated with one or more phosphors. The phosphors absorb a portion of light from the LED chip and emit a different wavelength of light such that the LED device emits a combination of light from each of the LED chip(s) and the phosphor(s). In one embodiment, the LED device emits what is perceived as white light resulting from a combination of light emission from the LED chip and the phosphor. In one embodiment according to the present subject matter, a white emitting device or system can consist of an LED chip that emits light in the blue wavelength spectrum and a phosphor that absorbs some of the blue light and re-emits light in the yellow wavelength spectrum. The device or system can therefore emit a white light combination of blue and yellow light. In other embodiments, the LED chips emit a non-white light combination of blue and yellow light as described in U.S. Pat. No. 7,213,940. LED chips emitting red light or LED chips covered by a phosphor that absorbs LED light and emits a red light are also contemplated herein. LED devices and systems described herein can comprise any suitable color temperature such as warm white or cool white color temperatures.

In some aspects, LED devices, systems, and methods described herein are configured for automotive headlight applications and comprise a color temperature between white and blue/white, such as between approximately 5000 K and 6000 K for standard low beam and/or high beam lights. However, devices, systems, and methods described herein are also configured for automotive headlight applications having a color temperature from approximately 6000 K to 8000 K, approximately 8000 K to 10,000 K, and approximately 10,000 to 15,000 K. Devices, systems, and methods configured for headlight applications having a color temperature of less than approximately 5000 K can also be provided.

In some aspects, LED devices, systems, and methods described herein are configured for street or roadway lighting applications comprising a natural white color temperature, such as a color temperature of approximately 4000 K. In some aspects, LED devices, systems, and methods described herein are configured for street or roadway lighting applications comprising a color temperature of between approximately 3700 K and 6200 K. However, street lighting having higher or lower color temperatures can also be provided.

LED chips can be coated with a phosphor using many different methods, with one suitable method being described in U.S. patent application Ser. Nos. 11/656,759 and 11/899,790, both entitled “Wafer Level Phosphor Coating Method and Devices Fabricated Utilizing Method”, and both of which are incorporated herein by reference in their entireties. Other suitable methods for coating one or more LED chips are described in U.S. Pat. No. 8,058,088 entitled “Phosphor Coating Systems and Methods for Light Emitting Structures and Packaged Light Emitting Diodes Including Phosphor Coating” which issued on Nov. 15, 2011, and the continuation-in-part application U.S. patent application Ser. No. 12/717,048 entitled “Systems and Methods for Application of Optical Materials to Optical Elements”, the disclosures of which are hereby incorporated by reference herein in their entireties. LED chips can also be coated using other methods such as electrophoretic deposition (EPD), with a suitable EPD method described in U.S. patent application Ser. No. 11/473,089 entitled “Close Loop Electrophoretic Deposition of Semiconductor Devices”, which is also incorporated herein by reference in its entirety. It is understood that LED devices, systems, and methods according to the present subject matter can also have multiple LED chips of different colors, one or more of which can be white emitting.

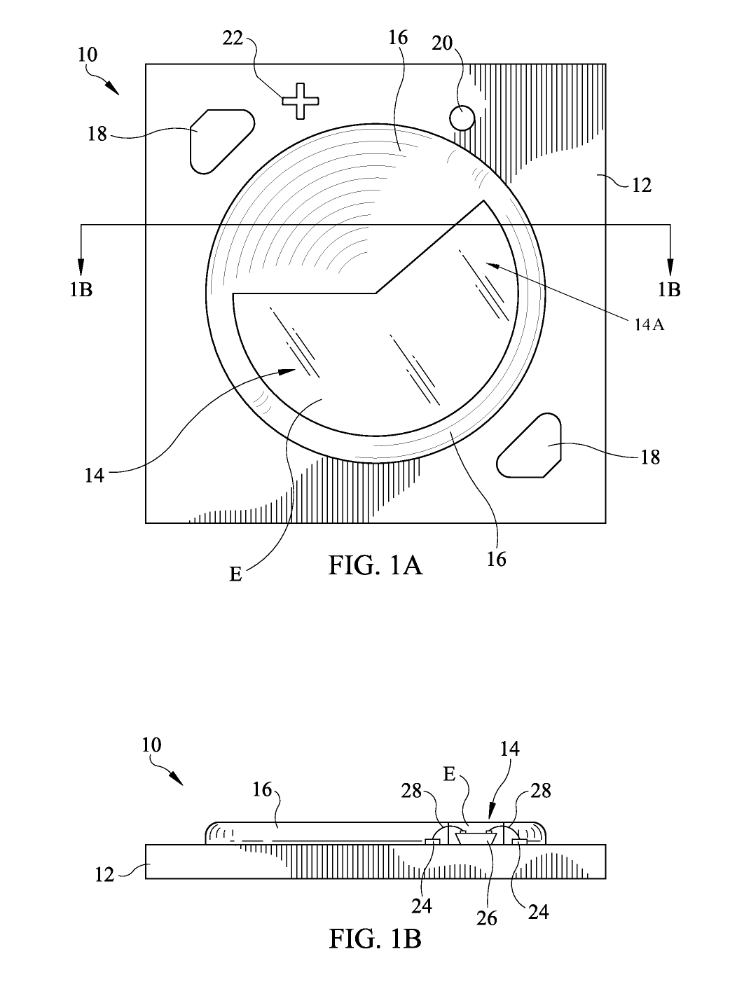

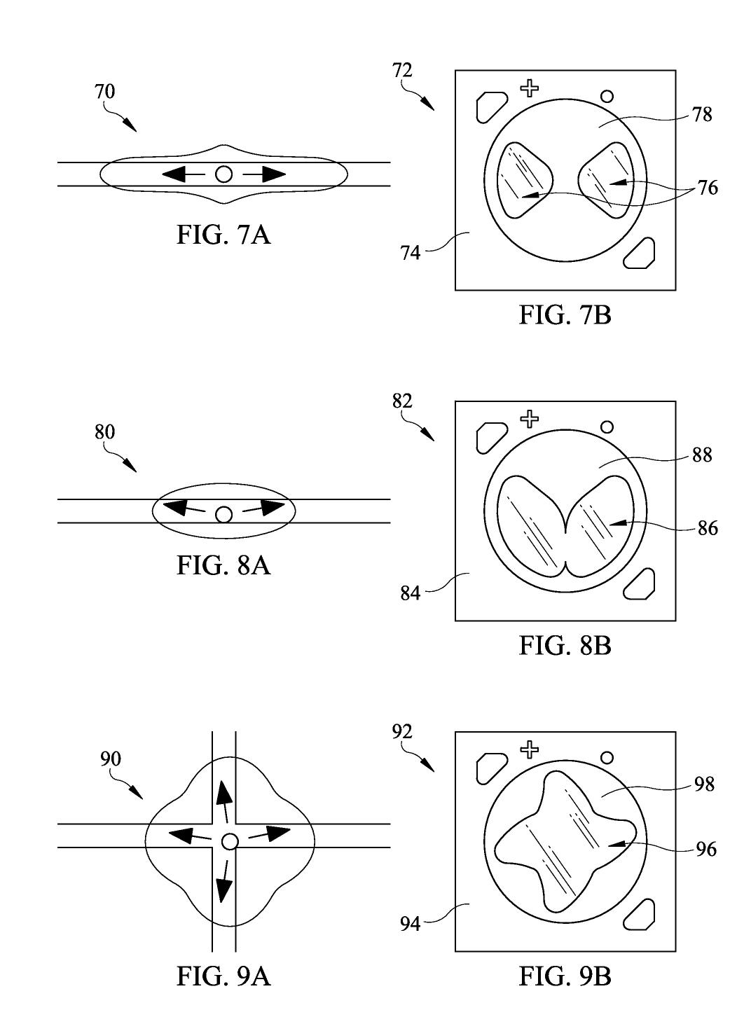

Referring now to FIGS. 1A and 1B, top perspective and sectional views, respectively, of a light emitting diode (LED) package or device, generally designated 10 are illustrated. LED device 10 can comprise a submount 12 over which one or more light emission areas, generally designated 14, are disposed. The one or more light emission areas 14 can be provided directly over one or more surfaces of submount 12, and include areas from which one or more LED chips (26, FIG. 1B) are configured to emit light. In some aspects, one or more emission areas 14 can be provided at any suitable location over LED device 10, for example, proximate a center of submount 12 or device 10 and/or off-center with respect to submount 12 or device 10. In some aspects, LED device 10 can comprise two or more emission areas 14 (e.g., FIG. 7B). The one or more emissions area 14 can comprise a substantially regular shape, irregular shape, symmetrical, or asymmetrical shape. The one or more emission areas 14 can emit substantially directional light (e.g., as opposed to omnidirectional light) that is substantially normal with respect to the upper surface of submount 12 over which LED chips (26, FIG. 1 B) are mounted.

Notably, device 10 comprises light source(s) or emission area(s) 14 that are correspondingly shaped as a desired light output or pattern of light. That is, one or more light emission areas 14 can directly provide the desired shape or output of beam pattern rather than specially constructed lenses. For example, emission area 14 in FIG. 1A is correspondingly shaped to a pattern for low beam headlight applications having an irregular cut off portion, generally designated 14A. Thus, this obviates the need for costly secondary optics to shape light. This allows the source of the light, for example, device 10 to be directly customized in shape, intensity, and/or color.

In some aspects, submount 12 can comprise any suitable or desired shape. In some aspects, submount 12 can comprise more than one outermost lateral edge, depending upon the shape. For example, submount 12 can comprise a square having four edges of equal length. Or, submount 12 can comprise a circle having only one edge, or circumference. Any size and/or shape of submount 12 shape is contemplated. In other embodiments, a submount 12 may not be necessary.

Submount 12 can comprise any suitable mounting substrate, for example, a portion of a lighting fixture, a printed circuit board (PCB), a metal core printed circuit board (MCPCB), an external circuit, or any other suitable submount over which lighting devices such as LED chips may mount and/or attach. Submount 12 can also comprise any size, and can be customized in size where desired. In some aspects and for example only and without limitation, submount 12 can comprise a compact and substantially square submount of approximately 10 millimeters (mm)×10 mm; approximately 22 mm×22 mm; approximately 25 mm×25 mm or more; or approximately 50 mm×50 mm or more. In other aspects, submount 12 can comprise any suitable dimension and/or shape, for example, a circular or rectangular shape.

Notably, the size(s), shape(s), and/or position of the one or more emission areas 14 can be customized to emit light of a customized and desired beam shape. Although devices 10 may be housed within or below a secondary lens lighting fixture or system, such devices and systems are advantageously devoid of costly customized optics for providing beam shaping.

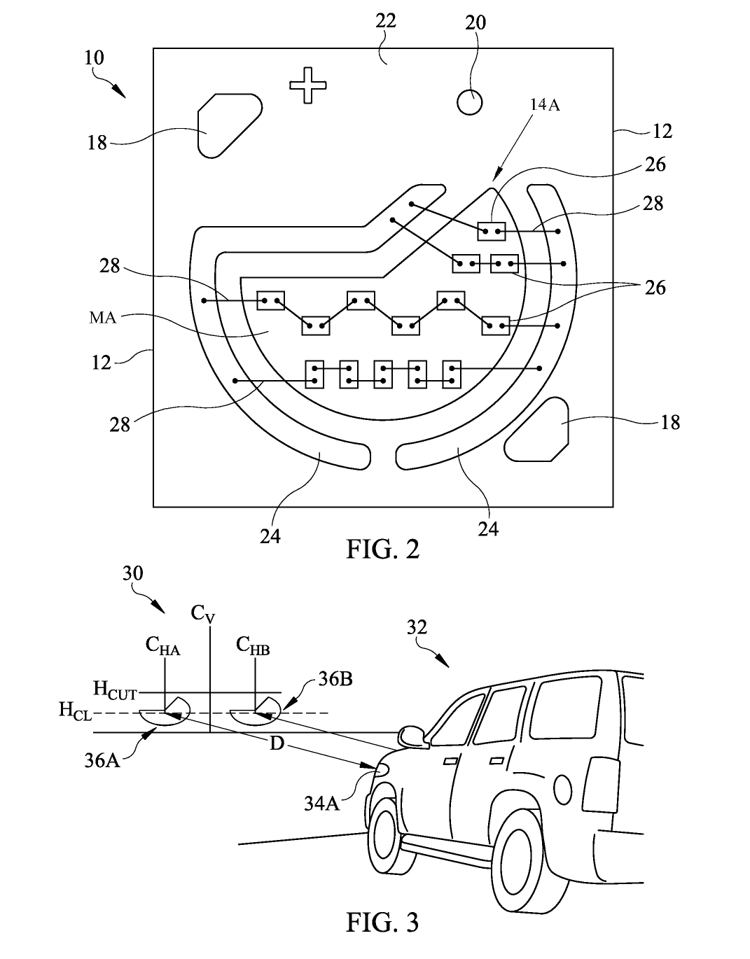

In some aspects, LED devices 10 provided herein can comprise one or more customized emission areas 14 for providing correspondingly shaped and customized beam patterns. In some aspects, a retention dam or retention material 16 can be provided about emission area 14. Notably, retention material 16 can be dispensed and/or comprise a dispensable material for easily providing one or more customized emission areas 14. That is, in some aspects, retention material 16 can be dispensed about an array of LED chips (e.g., 26, FIGS. 1A and 2) thereby defining a size and/or shape of emission area 14. In other aspects, emission area 14 can be defined by the size and/or shape of an array of LED chips (e.g., 26, FIGS. 1A and 2).

Retention material 16 can comprise any suitable thickness that can vary to any suitable height for retaining an encapsulant E. As FIG. 1A illustrates, for example and without limitation, retention material 16 can comprise at least one curved portion that can curve to extend at least proximate to one or more edges of submount 12. In some aspects, retention material 16 can comprise one or more concave portions, convex portions, or combinations of concave and convex portions. One or more straight portions can also be provided. Any configuration and/or shape of retention material 16, mounting area MA, and emission area 14 are hereby contemplated.

As FIG. 1A illustrates and in some aspects, emission area 14 comprises an irregular and/or asymmetrical shape for use in low beam automotive headlight applications. Low beam headlights provide a distribution of light designed to provide adequate forward and lateral illumination with limits on light directed towards the eyes of other road users for controlling glare. The beam pattern for low beam headlights is standardized and intended for use whenever other vehicles are present on the road ahead. The international Economic Commission for Europe (ECE) and North American Society for

Automotive Engineers (SAE) both establish standards for low beam headlights and require low beam patterns having a sharp, asymmetric cutoff for preventing significant amounts of light from being cast into the eyes of drivers of preceding or oncoming cars. That is, low beam headlamps are required to project an asymmetrical pattern that provides adequate forward and lateral illumination but controls glare by limiting light directed towards preceding or oncoming drivers.

In addition to providing asymmetric beam patterns, device 10 can be configured to provide intensity patterns that are asymmetric with respect to the intensity and/or color of light. For example and in some aspects, device 10 can be configured to emit an asymmetrical pattern of light that is more green on one side and more red on another side. In other aspects, device 10 can be configured to emit an asymmetrical pattern of light that is more intense on one side than on another side.

As FIG. 1A illustrates, emission area 14 generally and substantially corresponds to the standardized beam shape requirements for low beam headlights set forth by the ECE and SAE regulations and includes a substantially circular or semicircular shaped portion having a sharp, asymmetric cutoff 14A. In some aspects, emission area 14 comprises a shape or area that is less than or equal to approximately ⅝ of a circle for corresponding to standardized low beam headlight requirements.

As FIG. 1B illustrates, emission area 14 and/or portions thereof comprise LED chips 26 provided below an encapsulant E material. Encapsulant E can comprise a silicone encapsulant with or without phosphors. In some aspects, LED chips 26 are electrically connected to one or more electrically conductive traces 24 via electrically conductive wires 14 or wirebonds. Traces 24 are configured to pass electrical current through LED chips 26. In other aspects, horizontal LED chips 26 can be provided and can obviate the need for wires 28.

In some aspects, encapsulant E can comprise an encapsulant having a predetermined, or selective, amount of phosphors and/or lumiphors in an amount suitable for any desired light emission, for example, suitable for white light conversion. Encapsulant E can interact with light emitted from the LED chips 26 such that a perceived white light, or any suitable and/or desirable color or wavelength of light, can be observed. Any suitable combination of encapsulant and/or phosphors can be used, and combinations of different phosphors for resulting in desired light emission can be used. Encapsulant E can be substantially opaque such that emission area 14 can be substantially opaque (as illustrated in FIG. 1A), transparent, or semi-transparent depending upon, for example, the amount and type of phosphor used.

Generally referring to FIGS. 1A and 1B and in some aspects, traces 24 can receive electrical current from one or more attachment areas 18 (FIG. 1A) such as electrically conductive solder pads. For example, attachment areas 18 can electrically connect with portions of a power source (not shown) via solder for passing electrical current into device 10 via electrically conductive traces. Traces 24 can extend internally within portions of submount 12 for electrically and/or physically connecting portions of attachment areas 18 and traces 24.

Attachment areas 18 can comprise any suitable configuration, size, shape, and/or location and can comprise positive and negative electrode terminals through which an electrical current or signal can pass when connected to an external power source (not shown). In some aspects, one or more electrically conductive wires (not shown) can be attached and electrically connected to attachment areas 18 when welded, soldered, or by any other suitable attachment method. Electrical current or signal can pass through LED device 10 from the external wires electrically connected to attachment areas 18 and into customized emission area 14 for facilitating a customized light output and beam shape.

LED device 10 can further comprise one or more test points 20 located adjacent either a positive or negative side of the device for testing the electrical and/or thermal properties of LED device 10. Device 10 can also comprise one or more indicator signs or symbols 22 for denoting the electrical polarity for a given portion of LED device 10. For example, symbol 22 can comprise a “+” sign denoting the side of LED device 10 comprising the positive electrode terminal. A second symbol can be used if desired, for example, a “−” sign can be used to denote the side of LED device 10 comprising the negative electrode terminal. Any symbol 22 may be used alone, and any symbol other than a “+” or “−” sign can be provided.

As FIG. 1B illustrates, retention material 16 can be provided over at least a portion of wires 28 and/or over one or more electrostatic discharge (ESD) protection devices (not shown). Where used, ESD protection devices can, for example, comprise a Zener diode, an ESD varistor, an LED chip reverse biased to chips 26 within emission area 14, or any other suitable device.

Retention material 16 can be adapted for dispensing, or placing, about at least a portion of emission area 14. Thus, the shape or outline of retention material 16 can also be customized for outputting specific beam patterns. After placement of retention material 16, a filling material (e.g., encapsulant with or without phosphors) can be selectively filled to any suitable level within the space disposed between one or more inner walls of retention material 16. The filling material can be filled to a level equal to the height of retention material 16 or to any level above or below retention material. The level of filling material can be planar or curved in any suitable manner, such as concave or convex. In some, retention material 16 or dam can be offset from an edge of LED device 10. In other aspects, retention material 16 or dam can be aligned with an outermost edge of LED device 10 for more effectively utilizing space. Retention material 16 can be any size and/or shape, and can correspond to the shape of emission area 14 where desired.

Retention material 16 can comprise any material known in the art, for example, a silicone material comprising 7% fumed silica +3% TiO₂+methyl silicone. As illustrated in FIG. 1B, retention material 16 can be dispensed after wirebonding of the one or more LED chips 26 such that retention material 26 is disposed over and at least partially covers wire 28 to contain at least a portion, such as one end of each of wire within retention material 16. The addition of TiO₂ to retention material 16 can increase reflection about the emission area 14 to further to optimize light emission of LED device 10. Fumed silica can be added as a thixotropic agent. Dispersing retention material 16 can allow for any customized shape corresponding to any desired beam patter and can extend, curve, or otherwise conform to any shape over a submount or mounting surface thereby increasing the amount of space available to emit light. Dispensing retention material 16 may also allow LED device 10 to withstand higher voltages.

FIG. 2 is a top plan view of LED device 10 shown without encapsulant E and/or retention material 16, for illustration purposes. Device 10 can comprise one or more regularly shaped, irregularly shaped, non-circular, symmetrical, or asymmetrical mounting areas MA over which one or more LED chips 26 are mounted. In some aspects, an array of LED chips 26 can physically and/or electrically connect to portions of mounting area MA via epoxy, silicone, solder, paste, adhesive, flux, eutectic material, or any other suitable die attach material. In some aspects, the size and/or shape of mounting area MA can be customized to substantially correspond to the customized size and/or shape of emission area 14. In other aspects, mounting area MA can define a generally shaped area (e.g., a circle or square) over which an array of LED chips 26 may be provided. The customized shape of emission area 14 can then be defined by providing a customized size and/or shape of retention material 16 (FIGS. 1A and 1B) and filling retention material 16 with encapsulant E (FIGS. 1A and 1B).

In some aspects, mounting area MA can advantageously comprise a large area of device 10 over which LED chips 26 may be mounted. In some aspects, mounting areas MA and/or emission areas 14 can be provided proximate and/or adjacent to attachment areas 18 and/or outermost edges of device 10 for providing larger customized emission areas that more efficiently use submount space. Thus, as LED devices become dimensionally smaller, one or more customized mounting areas MA and/or emission areas 14 can be provided for more efficiently utilizing space by expanding via different sides and/or angles to curve and fit about other features of LED device, for example, attachment areas 18, to create more space from which LED chips 26 emit light.

As FIG. 2 further illustrates, one or more mounting areas MA can be provided between at least two electrical traces 24 for passing electrical current to LED chips 26 mounted thereto. LED chips 26 can be electrically connected in series, parallel, or combinations thereof. In some aspects, multiple strings of serially connected LED chips 26 can be connected in parallel between traces 24. Notably, one or more patterns of LED chips 26 can be provided within a single mounting area MA or emission area 14. LED chips 26 can be arranged in linear stings or non-linear strings of chips for more efficiently utilizing space, and for providing a more uniform light intensity.

One of the two traces 24 comprises an anode and the other a cathode. The electrical polarity can be denoted by one or more symbols 22. Mounting area MA and traces 24 can comprise any suitable electrical and thermally conductive materials and can comprise either the same or different materials. In some aspects, mounting area MA and traces 24 can comprise a layer of copper (Cu) or aluminum (Al) metal or alloy material deposited over submount using any suitable technique. An electrically insulating and reflective solder mask (not shown) can be disposed at least partially between mounting area MA and traces 24 for improving reflection of light from device 10.

LED device 10 can comprise a single customized (e.g., in size and/or shape) emission area 14 and a single respective mounting area MA, or device 10 can comprise more than one customized emission areas 14 and more than one respective mounting areas MA. In some aspects, a single mounting area MA can be provided, and multiple customized emission areas 14 can be provided over mounting area MA via customizing placement of retention material 16. Notably, each emission area 14 can comprise a uniform, undivided optical source adapted to produce a correspondingly shaped beam pattern some distance away from device 10, which obviates the need for secondary optics to provide beam shaping. Dispensing retention material 16 over and/or about mounting area MA can simplify the manufacturing process and degree of customization of a single lighting device or component.

In some aspects, retention material 16 can be disposed about and generally follow the shape of mounting area MA. In other aspects, retention material 16 can comprise any other shape either the same and/or different than that of mounting area MA. For example, retention material 16 can extend in any configuration about mounting area MA. Mounting area MA can comprise any electrically and/or thermally conductive material. Mounting area MA can also be thermally conductive and electrically isolating where desired. In some aspects, mounting area MA can comprise a thermally conductive material such as aluminum nitride (AlN) which can have a coefficient of thermal expansion similar to that of the one or more LED chips 26.

In some aspects, light emission area 14 can also be customized with respect to a shape, an intensity pattern, or a color pattern such that upon illumination of LED chips 26, a shape, intensity pattern, or color pattern of light emitted by device 10 (or a system incorporating device 10) substantially corresponds to the shape, intensity pattern, or color pattern of the light emission area 14.

LED chips 26 can comprise a high density array of chips mounted over a submount. LED chips 26 can comprise any suitable size, shape, and/or chip structure. For example, LED chips 26 can comprise a rectangle, square, or any other suitable shape. LED chips 26 can comprise a horizontal or vertical chip structure with or without bond pads.

Strings of LED chips 26 can comprise diodes of the same and/or different colors or wavelength bins, and different colors of phosphors can be used in the encapsulant E (FIG. 1B) in order to achieve emitted light of a desired color and/or wavelength. Each string of LED chips 26 can comprise any suitable number of chips electrically connected traces 24. The arrangements, patterns, and/or combination of multiple patterns of LED chips 26 herein can comprise an array for optimizing color uniformity and brightness of light emitted from LED device 10. In some aspects, the strings of LED chips 26 can be customized with respect to the overall shape of the collective strings. In other aspects, the strings of LED chips 26 are customized with respect to a light intensity pattern or a color pattern. That is, the LED strings can be configured to vary in intensity and/or color. The respective beam output via device 10 can correspond to the light intensity pattern and/or the color pattern.

Optional attachment areas (e.g., holes, openings, apertures, etc.) can be provided within a portion of submount 12 for facilitating attachment of LED device 10 to an external submount or surface. For example, an attachment areas can comprise an area for receiving screws, clips, pins, or other fasteners inserted through and/or attached to the at least one attachment area for securing device 10 to another member, structure, substrate or submount.

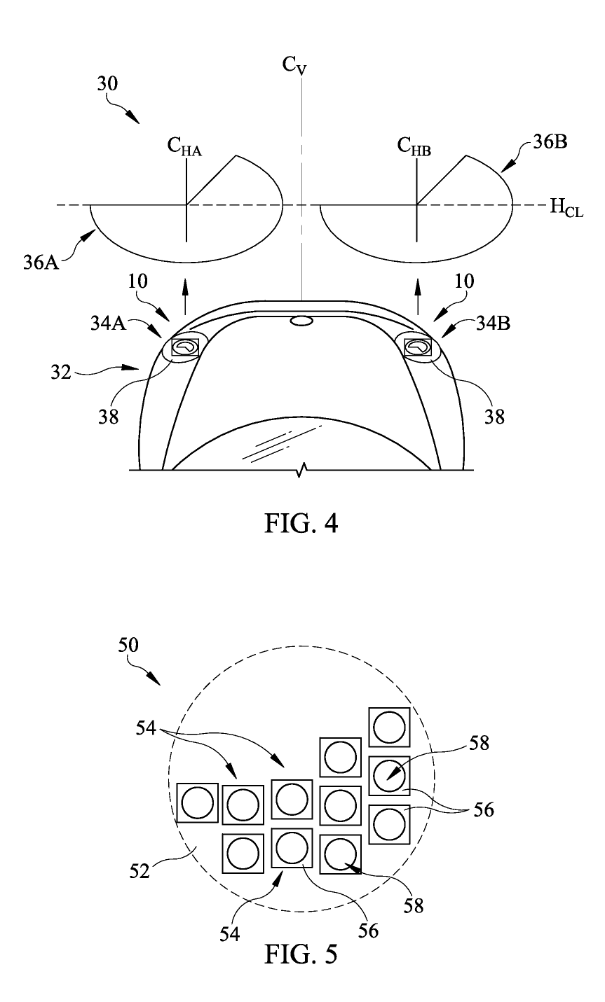

FIGS. 3 and 4 are schematic illustrations of beam patterns with an LED system generally designated 30. In some aspects, system 30 comprises an automotive lighting system for automotive lighting applications, such as for low beam headlights. Notably, the shape of low beam patterns produced by one or more devices 10 (FIG. 4) can be customized for use with a vehicle 32. For example, first and second headlights 34A and 34B of vehicle 32 can include devices 10 provided therein, where each device can have a customized emission area (e.g., 14, FIG. 1A) for providing first and second corresponding and customized beam patterns 36A and 36B, respectively. Beam patterns 36A and 36B can comprise a shape of light cast on a surface at some distance D away from the light source or device 10. Notably, devices 10 may include compact sizes but still be capable of producing large custom shaped beam patterns at least a distance D away from each headlight 34A and 34B. Distance D can for example comprise approximately 1 meter (m) or more, approximately 2 m or more, approximately 5 m or more, or approximately 10 m or more. In certain aspects, distance D as set forth in automotive standards is approximately 10 m.

As noted above and in some aspects, the shape of emission area 14 (FIG. 1A) of device 10 generally and substantially corresponds to the standardized beam shape required for low beam headlights set forth by the ECE and SAE regulations. As illustrated in FIGS. 3 and 4, first and second beam patterns 36A and 36B resultant from first and second low beam headlights 34A and 34B include a shape having an area of less than or equal to approximately ⅝ of a circle and a sharp asymmetric cutoff. This beam shape substantially corresponds to the shape of the lighting source provided via light emission areas 14 of device 10 (FIG. 1A).

In some aspects, beam patterns 36A and 36B are customized via customized devices 10. Beam patterns 36A and 36B are each non-circular and asymmetric with respect to vertical centerline of headlights 34A and 34B, or asymmetric with respect to C_{HA} and C_{HB}, respectively. Beam patterns 36A and 36B are also asymmetric with respect to horizontal centerline H_{CL}. The standardized asymmetric portions of beam patterns 36A and 36B extend towards the horizontal line designated H_{CUT}. In certain aspects, the height of the asymmetrical cutoff as measured between H_{CL} and H_{CUT} is approximately 130 mm as set forth in automotive standards.

In some aspects, the pair of beam patterns 36A and 36B are collectively symmetric about a centerline of the vehicle C_{V}. In some aspects, this provides beam patterns having an adequate lateral and vertical spread, while vehicles on the opposing side of the road will not experience excessive glare from headlights 34A and 34B.

In some aspects, device 10 can be at least partially disposed below a simple lens 38 of head lights 34A and 34B. Lens 38 can protect the electrical devices and systems housed therein, and can provide a simple, protective lens. Lens 38 is devoid of a secondary optics configured to affect beam pattern or intensity patterns 36A and 36B.

FIG. 5 is another is another example of an LED device, generally designated 50. LED device 50 can comprise any suitably sized and/or shape of submount 52 and is shown in phantom lines for illustration purposes. One or more chip on board (COB) LED chips and/or LED packages generally designated 54 can be provided over submount 52. Where packaged LED chips are used, each package 54 can comprise a mounting substrate or submount 56 and a lens generally designated 58. An LED chip can be provided below each lens 58.

Notably, the light source including COB LED chips and/or LED packages 54 can be arranged in any customized shape for emitting light in a customized beam pattern at some distance away. For example, LED packages 54 can be provided in a pattern corresponding to a standardized low beam pattern, having a semicircle and an asymmetrical cutoff portion. Packages 54 of device 50 comprise an emission area from which light is emitted. In some aspects, a resultant beam pattern emitted via device 50 corresponds to beam patterns 36A and 36B shown in FIGS. 3 and 4. That is, device 50 can be configured to emit a beam pattern customized for the automotive industry, or any other suitable application in any other suitable industry.

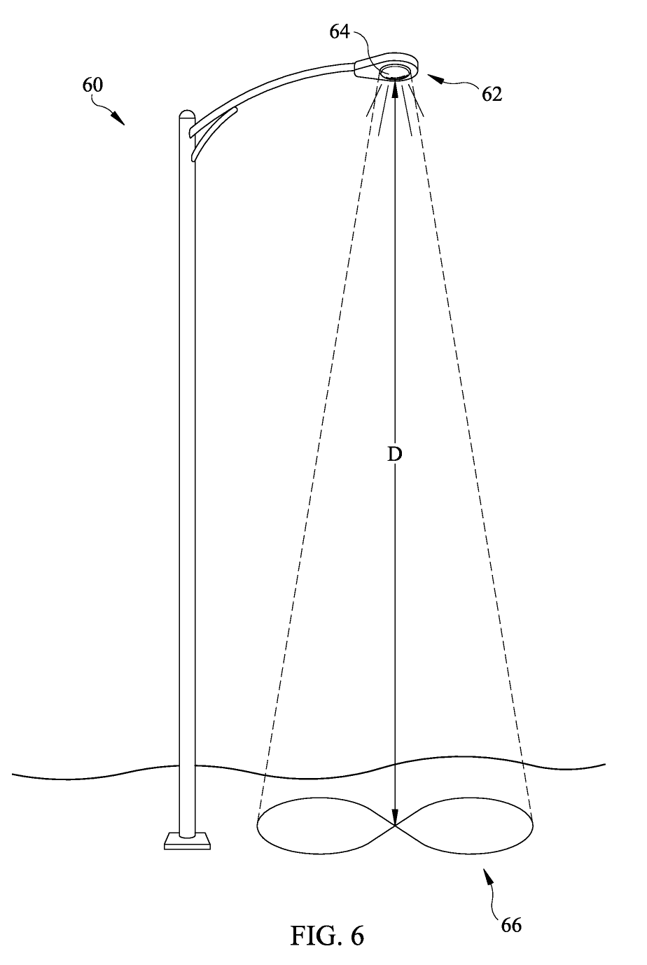

FIG. 6 illustrates an LED system, generally designated 60. LED system 60 comprises a street or roadway lighting system for street or roadway lighting applications. System 60 is configured to emit customized beam patterns and/or intensity patterns conforming to various standardized street lighting patterns set forth by the Illumination Engineering Society of North America (IESNA) standards. System 60 comprises a light source of light emitting portion generally designated 62 provided within a simple outermost housing 64. Housing 64 can comprise a bulb or lens. In some aspects, light emitting portion 62 can include a device comprising a light emission area configured to establish a corresponding beam pattern 66 located a distance D away from light emitting portion 62. In some aspects, the emission area of light emitting portion 62 corresponds in shape to the shape of beam pattern 66. Beam pattern 66 can be cast over a surface (e.g., a floor, grass, ground, or roadway) provided at a distance D away from portion 62. Distance D can be a distance of approximately 1 m or more, approximately 2 m or more, approximately 3 m or more, approximately 5 m or more, approximately 10 m or more, or more than approximately 10 m.

In some aspects, housing 64 is a simple lens and does not affect beam shaping. Housing 64 can however optionally comprises a diffuser configured to provide more even light extraction from light emitting portion 62 where desired. LED devices and systems disclosed herein can advantageously consume less energy, cost less, and perform better while emitting true white or any desired white light illumination. LED devices and systems disclosed herein can also advantageously maximize the amount of emission area available by utilizing customized shaped light emission areas. In addition, LED devices, systems, and methods disclosed herein can advantageously be customized for a variety of lighting applications.

FIGS. 7A to 9B illustrate devices for systems and methods for providing desired beam shaping according to the disclosure herein. The IESNA lighting handbook provides classification definitions for different types of street or roadway lighting. The different types of street and roadway lighting include differently shaped beam and/or light intensity patterns. Notably, devices, systems, and methods provided herein are configured for use to provide one or more types of roadway lighting, in addition to other custom lighting applications.

FIG. 7A is a beam pattern or light intensity pattern, generally designated 70 associated with Type I illumination. Type I illumination includes direct illumination in two directions along the direction of the roadway (if the road is a single road) and/or in a straight directional pattern at a cross section. FIG. 7B is a device, generally designated 72, that is configured to produce the Type I illumination pattern 70 of FIG. 7A. In some aspects, device 72 can directly provide Type I illumination via provision of one or more custom shaped emission areas generally designated 76. Emission areas 76 containing LED chip arrays are provided over a submount 74 and surrounded by retention material 78. The shape of emission areas 76 substantially corresponds to the desired beam pattern or illumination pattern produced by Type I lighting.

For example, emission areas 76 are symmetrical within retention material 78 for providing illumination in two directions along a roadway. Emission areas 76 can be narrowed or widened to produce wider or narrow beam patterns at some distance away from the source of roadway lighting, typically in a system (e.g., FIG. 6) where the source is positioned above the roadway.

FIG. 8A is a beam pattern or light intensity pattern, generally designated 80, associated with Type III illumination. Type III illumination is a different and angled illumination as compared to Type I, where the angle of illumination from normal is narrower to reflect a smaller coverage area. FIG. 8B is a device, generally designated 82, that is configured to produce the Type III illumination pattern 80 of FIG. 8A. In some aspects, device 82 can directly provide Type III illumination via provision of one or more custom shaped emission areas 86.

Emission area 86 can comprise LED chips disposed within an encapsulant and is provided over a submount 84 and surrounded by retention material 88. The shape of emission area 86 substantially corresponds to the desired beam pattern or illumination pattern produced by Type III lighting. For example, emission area 86 includes two portions that are angled with respect to each other and with respect to a normal axis for casting an angled beam pattern over a roadway.

FIG. 9A is a beam pattern or light intensity pattern, generally designated 90, associated with Type II, 4-way illumination. Type II, 4-way illumination is emitted by lighting fixtures or systems for directing light at an angle to normal in either two directions, or in four directions as shown in FIG. 9A.

FIG. 9B is a device, generally designated 92 for use with LED chips. Device 92 is configured to produce the Type II, 4-way illumination pattern 90 of FIG. 9A. In some aspects, device 92 can directly provide Type II, 4-way illumination via provision of one or more custom shaped emission areas 96.

Emission area 96 can comprise LED chips within an encapsulant (e.g., similar in form and function to emission area 14 in FIG. 1B) and is provided over a submount 94 and surrounded by retention material 98. The shape of emission area 96 substantially corresponds to the desired beam pattern or illumination pattern produced by Type II, 4-way lighting. For example, emission area 96 includes four portions configured to cast a 4-way, angled beam pattern over a roadway. Emission area 96 can be non-circular and/or asymmetric in shape.

Devices, systems, and methods for providing other types of roadway illumination (e.g., Type IV, Type V, etc.) can also be provided. In some aspects devices 72, 82, and/or 92 of FIGS. 7B, 8B, and 9B, respectively, can be optionally provided within a fixture having a simple lens or housing (not shown); however a costly secondary optics for the purpose of affecting beam and/or intensity patterns or beam shaping is obviated.

A method of providing devices and systems with customized beam shaping is also provided. In some aspects, the method comprises providing a lighting source, such as an LED device or system described herein, the device or system having a customized light emission area comprised of a plurality of LED chips. The light emission area can be customized with respect to a shape of the LED chips, a pattern of LED chip intensity, or a pattern of LED chip color. For example, LEDs can be arranged according to an overall LED array shape, LED chip intensity, or LED chip color. The method can further comprise passing current through the device or system for illuminating the LED chips and providing a beam pattern of light that corresponds to the shape, intensity, and/or color of the LED chips or light emission area of the LED device or system.

Embodiments as disclosed herein may provide one or more of the following beneficial technical effects: reduced cost of LED devices; reduced size or volume of LED devices; customized beam shaping; easily customized devices; easily customized beam patterns; improved beam shaping; improved color rendering and intensity; improved manufacturability; improved light efficiency; improved ability to vary beam size, beam pattern, and/or direction of light output by LED devices and systems.

While the subject matter has been has been described herein in reference to specific aspects, features, and illustrative embodiments, it will be appreciated that the utility of the subject matter is not thus limited, but rather extends to and encompasses numerous other variations, modifications and alternative embodiments, as will suggest themselves to those of ordinary skill in the field of the present subject matter, based on the disclosure herein. Various combinations and sub-combinations of the structures and features described herein are contemplated and will be apparent to a skilled person having knowledge of this disclosure. Any of the various features and elements as disclosed herein may be combined with one or more other disclosed features and elements unless indicated to the contrary herein. Correspondingly, the subject matter as hereinafter claimed is intended to be broadly construed and interpreted, as including all such variations, modifications and alternative embodiments, within its scope and including equivalents of the claims.

What is claimed is:

1. A light emitting device, comprising:
a submount; and
a light emission area configured to cast light towards a surface that is a distance away from the submount, the light emission area comprising a plurality of light emitting diode (LED) chips mounted over the submount;
wherein at least some of the LED chips are provided in a first non-circular shape, such that upon illumination of the LED chips, a resultant beam pattern of light on the surface is substantially the same as the first shape.

2. The device of claim 1, wherein at least some of the plurality of LED chips are provided according to a first intensity pattern, such that upon illumination of the LED chips, a resultant beam intensity pattern is substantially the same as the first intensity pattern.

3. The device of claim 1, wherein at least some of the plurality of LED chips are provided according to a first color pattern, such that upon illumination of the LED chips, a resultant color beam pattern is substantially the same as the first intensity pattern.

4. The device of claim 1, wherein the first shape corresponds to a standardized shape for low beam headlights.

5. The device of claim 1, wherein the first shape comprises a semicircular shaped portion with an asymmetrical cutoff portion.

6. The device of claim 1, wherein the first shape corresponds to the shape defined by Type I roadway lighting.

7. The device of claim 1, wherein the first shape corresponds to the shape defined by Type II roadway lighting.

8. The device of claim 1, wherein the first shape corresponds to the shape defined by Type III roadway lighting.

9. The device of claim 1, wherein the first shape corresponds to the shape defined by Type IV roadway lighting.

10. The device of claim 1, wherein the first shape corresponds to the shape defined by Type V roadway lighting.

11. The device of claim 1, wherein the LED chips are surrounded at least partially by encapsulant.

12. The device of claim 1, wherein the light emission area is provided between at least two walls of a retention dam.

13. A light emitting system, comprising:
a light emitting device comprising:
a submount; and
a light emission area comprising a plurality of light emitting diode (LED) chips mounted over the submount;
wherein the light emission area comprises a specific shape, intensity pattern, or color pattern; and
a housing disposed about a portion of the light emitting device;
wherein, upon illumination of the LED chips, a shape, intensity pattern, or color pattern of light emitted thereby substantially corresponds to the shape, intensity pattern, or color pattern of the light emission area.

14. The system of claim 13, wherein the shape corresponds to a standardized shape for low beam headlights.

15. The system of claim 13, wherein the shape comprises a semicircular shaped portion with an asymmetrical cutoff portion.

16. The system of claim 13, wherein the shape corresponds to the shape defined by one of a Type I, Type II, Type III, Type IV, or Type V roadway lighting.

17. The system of claim 13, wherein the LED chips are surrounded at least partially by encapsulant.

18. The system of claim 13, wherein the light emission area is provided between at least two walls of a retention dam.

19. The system of claim 13, wherein the housing comprises a lens or bulb.

20. The system of claim 13 comprising a vehicle headlight.

21. The system of claim 13 comprising a street light.

22. A method of providing customized beam shaping, the method comprising:
providing a plurality of LED chips over a submount;
arranging the plurality of LED chips within a shape, according to LED chip intensity, or according to LED chip color; and
illuminating the LED chips, such that upon illumination, a resultant beam pattern of light corresponds to the shape, intensity, or color of the LED chips.

23. The method of claim 22, wherein arranging the plurality of LED chips comprises arranging the LED chips in a shape corresponding to a standardized shape for low beam headlights.

24. The method of claim 22, wherein arranging the plurality of LED chips comprises arranging the LED chips in a shape comprising a semicircular shaped portion with an asymmetrical cutoff portion.

25. The method of claim 22, wherein arranging the plurality of LED chips comprises arranging the LED chips in a shape corresponding to the shape defined by one of a Type I, Type II, Type III, Type IV, or Type V roadway lighting.

26. The method of claim 22, further comprising dispensing a dam about the LED chips.

27. The method of claim 27, further comprising encapsulating the LED chips.

28. The method of claim 22, further comprises providing the LED chips and submount within a housing.
